(19) United States
(12) Patent Application Publication
(10) Pub. No.: US 2013/0178016 A1
(43) Pub. Date: Jul. 11, 2013

(54) METHODS OF FABRICATING A PACKAGE-ON-PACKAGE DEVICE AND PACKAGE-ON-PACKAGE DEVICES FABRICATED BY THE SAME

(71) Applicant: Samsung Electronics Co., Ltd., Suwon-Si (KR)

(72) Inventors: Choongbin YIM, Cheonan-si (KR); Eunchul AHN, Yongin-Si (KR); Taesung PARK, Cheonan-si (KR); Hak-kyoon BYUN, Hwaseong-si (KR); Yongkwan LEE, Hwaseong-si (KR)

(73) Assignee: Samsung Electronics Co., Ltd., Suwon-Si (KR)

(21) Appl. No.: 13/736,551

(22) Filed: Jan. 8, 2013

(30) Foreign Application Priority Data
Jan. 11, 2012 (KR) 10-2012-0003434

(51) Int. Cl. H01L 25/00

(52) U.S. Cl. 438/108

(57) ABSTRACT

Methods of fabricating a package-on-package device and package-on-package devices fabricated by the same may be provided. According to inventive concepts, a back-grinding of a semiconductor chip to a target thickness may be performed after the semiconductor chip is molded by a molding layer. Accordingly, the semiconductor chip is relatively thick while forming a molding layer, and thus less susceptible to a warpage phenomenon, which for instance may occur during the forming a molding layer. Thus, relatively thin package-on-package device, which is less susceptible to the warpage phenomenon, may be achieved.

### CROSS-REFERENCE TO RELATED APPLICATIONS

This U.S. non-provisional patent application claims priority under 35 U.S.C. §119 to Korean Patent Application No. 10-2012-0003434, filed on Jan. 11, 2012, the entirety of which is incorporated by reference herein.

### BACKGROUND

The inventive concepts relate to methods of fabricating a package-on-package device and/or package-on-package devices fabricated by the same.

With development of an electronic industry, higher performance, faster speed, and smaller sizes of electric components have been in steady demand. In response to these trends, various semiconductor mounting techniques have been suggested. For example, a plurality of semiconductor chips may be mounted on one package board or a semiconductor package may be stacked on another semiconductor package. Particularly, a package-on-package (PoP) device, which is formed by stacking semiconductor packages, may include each of the stacked semiconductor packages including a semiconductor chip and a package board. Thus, a total thickness of the package-on-package device may increase. To reduce the total thickness of the package-on-package device, a thin semiconductor chip may be used in each of the stacked packages. However, the thin semiconductor chip and/or each of the stacked packages may be warped.

### SUMMARY

Inventive concepts may provide methods of fabricating a package-on-package device capable of improving warpage problems and thinning a thickness thereof.

The inventive concepts may also provide package-on-package devices having a reduced degree of warpage and a relatively thin thickness.

According to example embodiments, a method of fabricating a package-on-package device may include fabricating a lower semiconductor package, and mounting an upper semiconductor package on the lower semiconductor package. The fabricating the lower semiconductor package may include mounting a lower semiconductor chip on a lower package board in a flip chip bonding method, forming a lower molding layer covering at least a sidewall of the lower semiconductor chip and covering the lower package board, and performing a grinding process to remove an upper portion of the lower molding layer and an upper portion of the lower semiconductor chip.

In some embodiments, the method may further include forming an inner solder ball on the lower package board beside the lower semiconductor chip before forming the lower molding layer.

In other embodiments, the method may further include partially removing the lower molding layer using a laser to form a connecting hole. The grinding may not expose the inner solder ball, but the connecting hole formed by partially removing the lower molding layer may expose the inner solder ball.

In still other embodiments, the upper semiconductor package may include a pad opposite to the lower molding layer. Further, mounting the upper semiconductor package may include locating a preliminary solder ball contacting the pad in the connecting hole, and melting and bonding the preliminary solder ball and the inner solder ball to each other.

In yet other embodiments, performing the grinding process may expose the inner solder ball.

In yet still other embodiments, the method may further include forming an underfill resin layer filling a space between the lower semiconductor chip and the lower package board before forming the lower molding layer. The grinding process may expose the underfill resin layer.

In yet still other embodiments, the lower molding layer may include a resin layer and a plurality of filler particles dispersed in the resin layer, and the grinding may grind at least one of the filler particles.

In yet still other embodiments, the filler particle exposed at a top surface of the lower molding layer may be removed by the grinding such that a filler hole may be formed at the top surface of the lower molding layer and the filler particle may have a diameter less than about 50 μm.

In yet still other embodiments, the grinding may be performed to the upper portions of the lower molding layer and the lower semiconductor chip in the same direction such that the same pattern may be formed at top surfaces of the lower molding layer and the lower semiconductor chip.

According to example embodiments, a package-on-package device may include a lower semiconductor package and at least one upper semiconductor package mounted on the lower semiconductor package. The lower semiconductor package may include a lower package board, a lower semiconductor chip mounted on the lower package board in a flip chip bonding method, and a lower molding layer covering a sidewall of the lower semiconductor chip and the lower package board and exposing a top surface of the lower semiconductor chip. The lower molding layer may include a resin layer and a plurality of filler particles dispersed in the resin layer, and at least one filler particle exposed at a top surface of the lower molding layer among the plurality of filler particles may have a planarized top surface.

In some embodiments, the top surface of the lower molding layer may have the same pattern as the top surface of the lower semiconductor chip.

In other embodiments, the top surface of the lower molding layer may include at least one filler hole.

In still other embodiments, a diameter of the filler hole may be smaller than about 50 μm.

In yet other embodiments, a surface roughness of the top surface of the lower molding layer may be substantially the same as a surface roughness of the top surface of the lower semiconductor chip.

In yet still other embodiments, a center line average roughness Ra or a ten point height of irregularities Rz of a surface roughness of a top surface of the lower semiconductor chip may be substantially equal to or less than about 25 μm.

In yet still other embodiments, the device may further include a connecting hole disposed in the lower molding layer, and an inner solder ball disposed on the lower package board and exposed through the connecting hole.

In yet still other embodiments, the device may further include an underfill resin layer disposed between the lower semiconductor chip and the lower package board. The underfill resin layer may extend to be disposed between the lower molding layer and the sidewall of the lower semiconductor chip.

In yet still other embodiments, a top surface of the underfill resin layer may have a same pattern as the top surface of the lower molding layer.

In yet still other embodiments, the upper semiconductor package may be different from the lower semiconductor package.

In yet still other embodiments, the upper semiconductor package may include an upper package board, at least one upper semiconductor chip mounted on the upper package board in a wire bonding method, and an upper molding layer covering the at least one upper semiconductor chip and the upper package board.

In still another example embodiment, a package-on-package device may include a lower semiconductor package having a lower package board, a lower semiconductor chip mounted on the lower package board in a flip chip bonding method, and a lower molding layer covering a sidewall of the lower semiconductor chip and the lower package board and exposing a top surface of the lower semiconductor chip, and at least one upper semiconductor package mounted on the lower semiconductor package, the upper semiconductor package having an upper package board, at least one upper semiconductor chip mounted on the upper package board in a wire bonding method, and an upper molding layer covering the at least one upper semiconductor chip and the upper package board. The lower molding layer may include a resin layer and a plurality of filler particles dispersed in the resin layer, and at least one filler particle exposed at a top surface of the lower molding layer among the plurality of filler particles may have a planarized top surface.

According to example embodiments, a method of fabricating a first semiconductor package may include flip chip bonding a first semiconductor chip onto a first package board, forming a molding layer to cover the first package board and at least a sidewall of the first semiconductor chip; and removing an upper portion of the molding layer and an upper portion of the first semiconductor chip to a target thickness.

In example embodiments, the method may further include forming a first solder ball on the first package board, and the first solder ball is formed around the first semiconductor chip before the forming a molding layer.

In example embodiments, the method may further include forming a connecting hole through the molding layer, and the connecting hole may expose the first solder ball.

In example embodiments, forming a connecting hole may be carried out at least one of before and after the removing.

In example embodiments, the removing may expose the top surface of the first solder ball.

In example embodiments, the method may further include mounting a second semiconductor package onto the first semiconductor package, and the second semiconductor package may include a second package board and a second semiconductor chip thereon. The first and the second semiconductor packages may be electrically coupled to each other, and thus constitute a package-on-package device.

In example embodiments, the method may further include forming a second solder ball on a surface of the second package board and the surface may face the first semiconductor package.

In example embodiments, the first solder ball formed on the first semiconductor package may contact the second solder ball formed on the second semiconductor package.

In example embodiments, the first solder ball may be connected to the second solder ball in the connecting hole, which is formed in the first semiconductor package.

In example embodiments, the method may further include thinning the first semiconductor chip to an intermediate thickness before the removing.

### BRIEF DESCRIPTION OF THE DRAWINGS

The inventive concepts will become more apparent and more readily appreciated from the following description of example embodiments, taken in conjunction with the accompanying drawings of which:

FIG. 1 is a flow chart illustrating a method of fabricating a package-on-package device according to example embodiments of inventive concepts;

FIGS. 2, 3A, 4A, 5A, and 6 to 10 are cross-sectional views illustrating a method of fabricating a package-on-package device according to the example embodiments of FIG. 1;

FIG. 3B is a cross-sectional view illustrating a modified example of FIG. 3A;

FIGS. 4B and 5B are cross-sectional views illustrating a modified example of the example embodiments of FIG. 1;

FIGS. 11A to 11D are enlarged views of a portion ‘A’ of FIG. 5A or FIG. 10;

FIGS. 12 to 14 are cross-sectional views illustrating a method of fabricating a package-on-package device according to example embodiments of inventive concepts;

FIGS. 15 to 17 are cross-sectional views illustrating a method of fabricating a package-on-package device according to example embodiments of inventive concepts;

FIG. 18 is a cross-sectional view illustrating a package-on-package device according to example embodiments of inventive concepts;

FIG. 19 is a cross-sectional view illustrating a package-on-package device according to example embodiments of inventive concepts;

FIG. 20 is a perspective view illustrating an electronic device including at least one of package-on-package devices according to the example embodiments of inventive concepts;

FIG. 21 is a system block diagram illustrating another example of an electronic device applied with at least one of package-on-package devices according to example embodiments of inventive concepts; and

FIG. 22 is a block diagram illustrating an example of electronic systems including at least one of package-on-package devices according to example embodiments of inventive concepts.

### DETAILED DESCRIPTION OF EXAMPLE EMBODIMENTS

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as ideal example views of the inventive concept. Accordingly, shapes of the example views may be modified according to manufacturing techniques and/or allowable errors. Therefore, the example embodiments of the inventive concepts are not limited to the specific shape illustrated in the example views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concepts. Example embodiments of aspects of the present inventive concepts explained and illustrated herein include their complementary counterparts. The same or similar reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

### First Embodiment

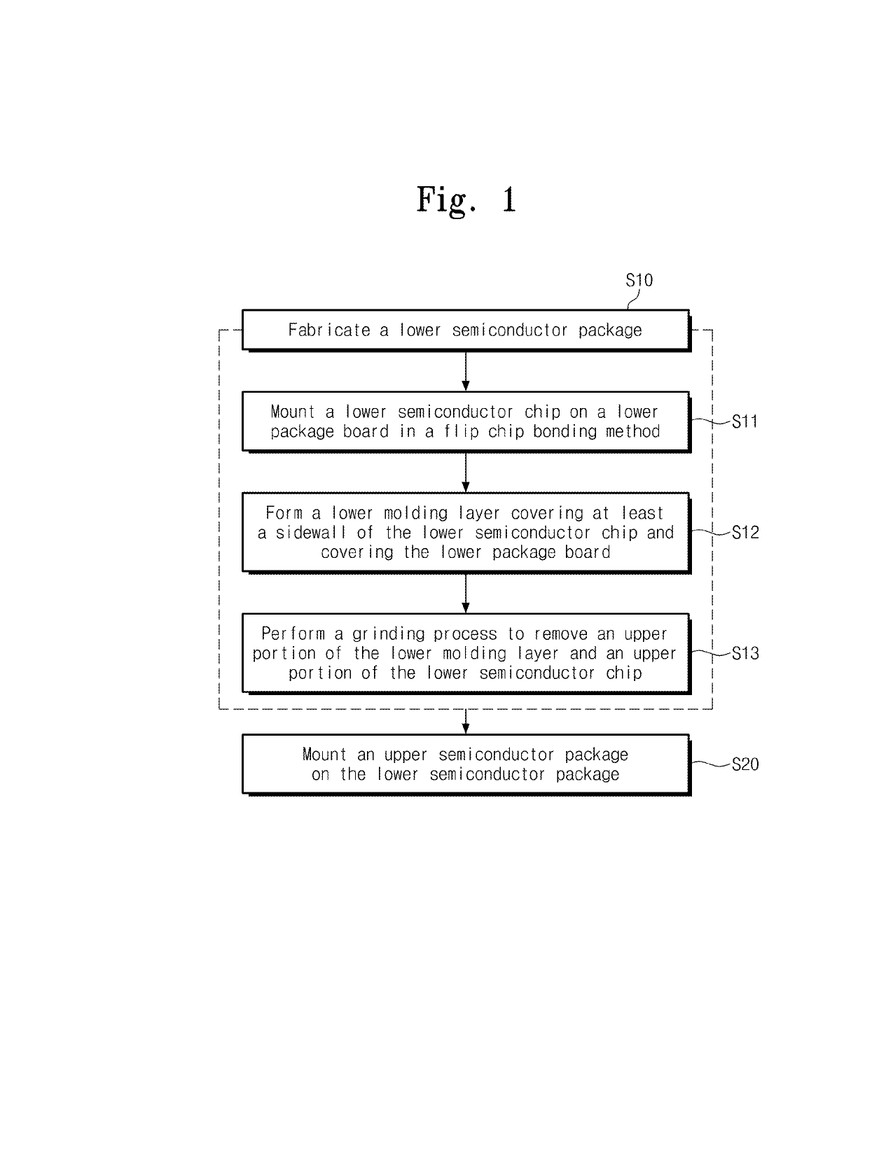

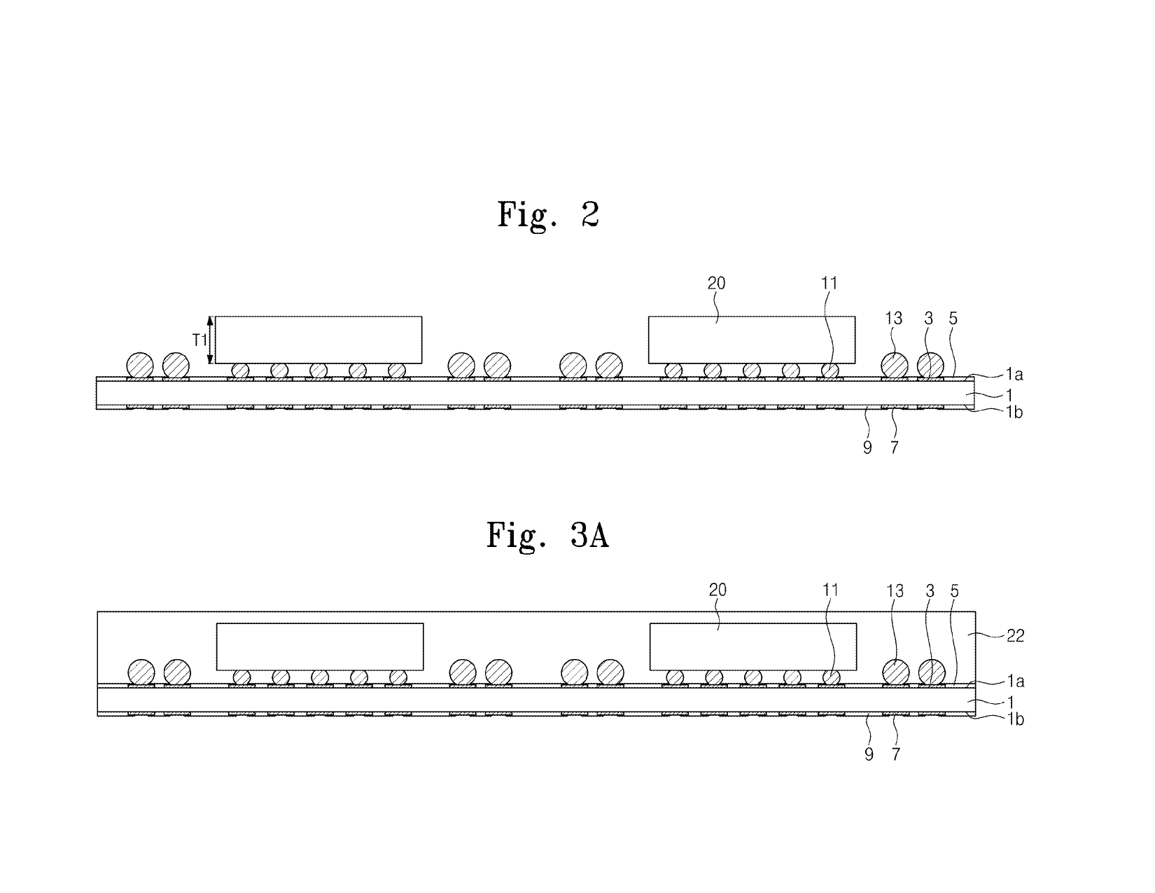

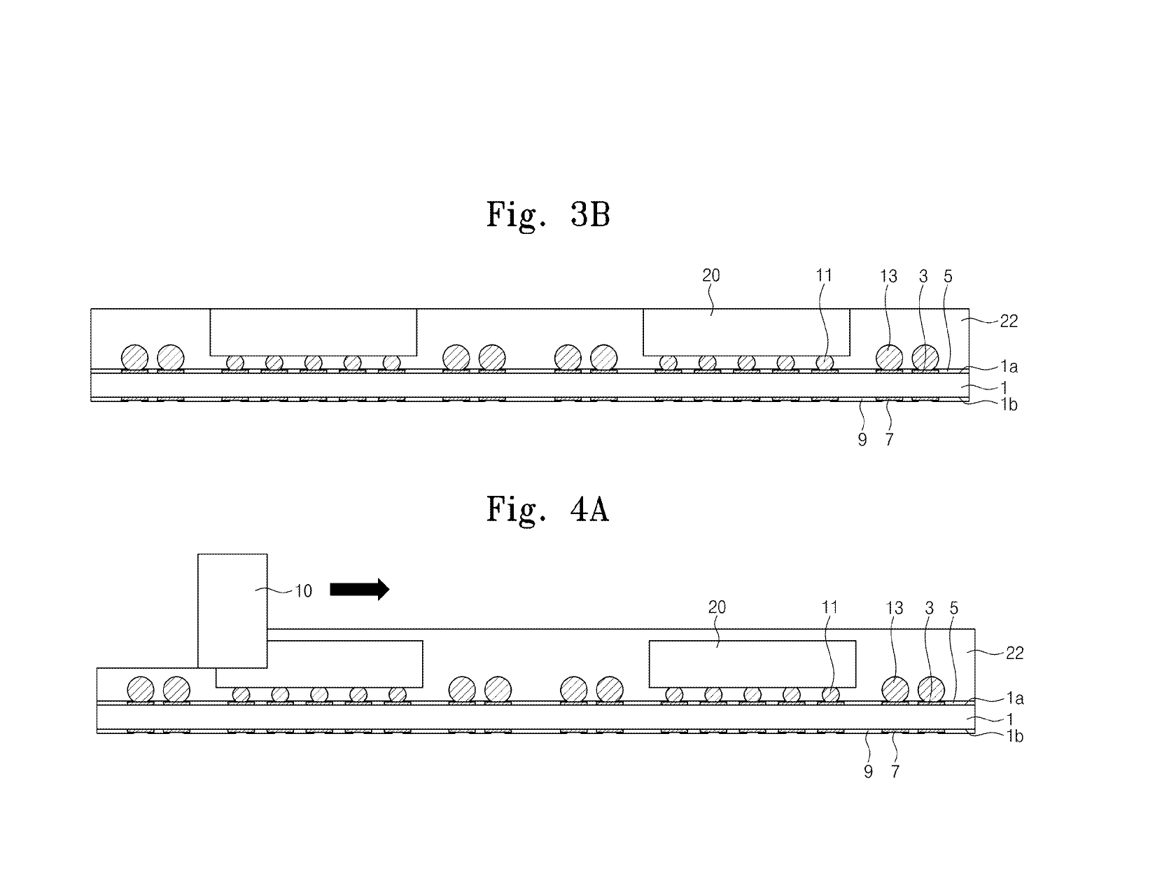

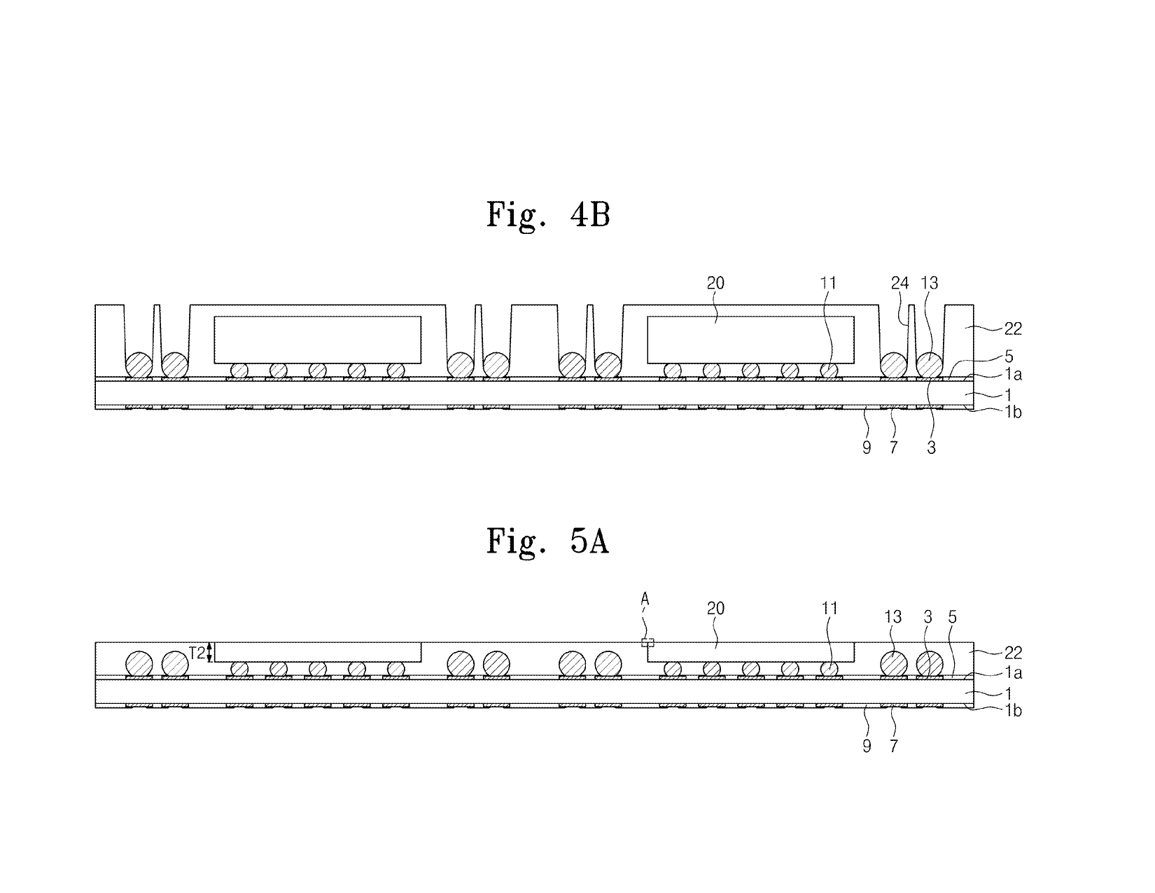

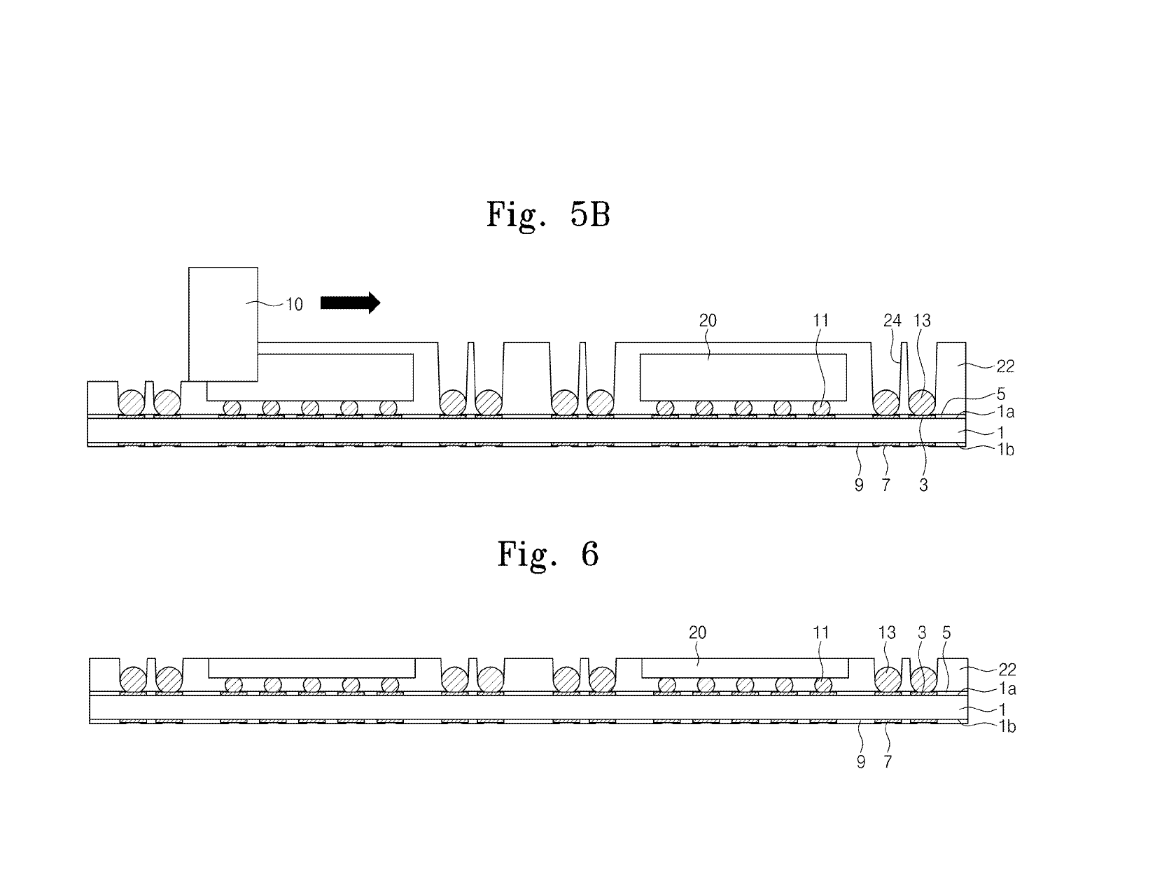

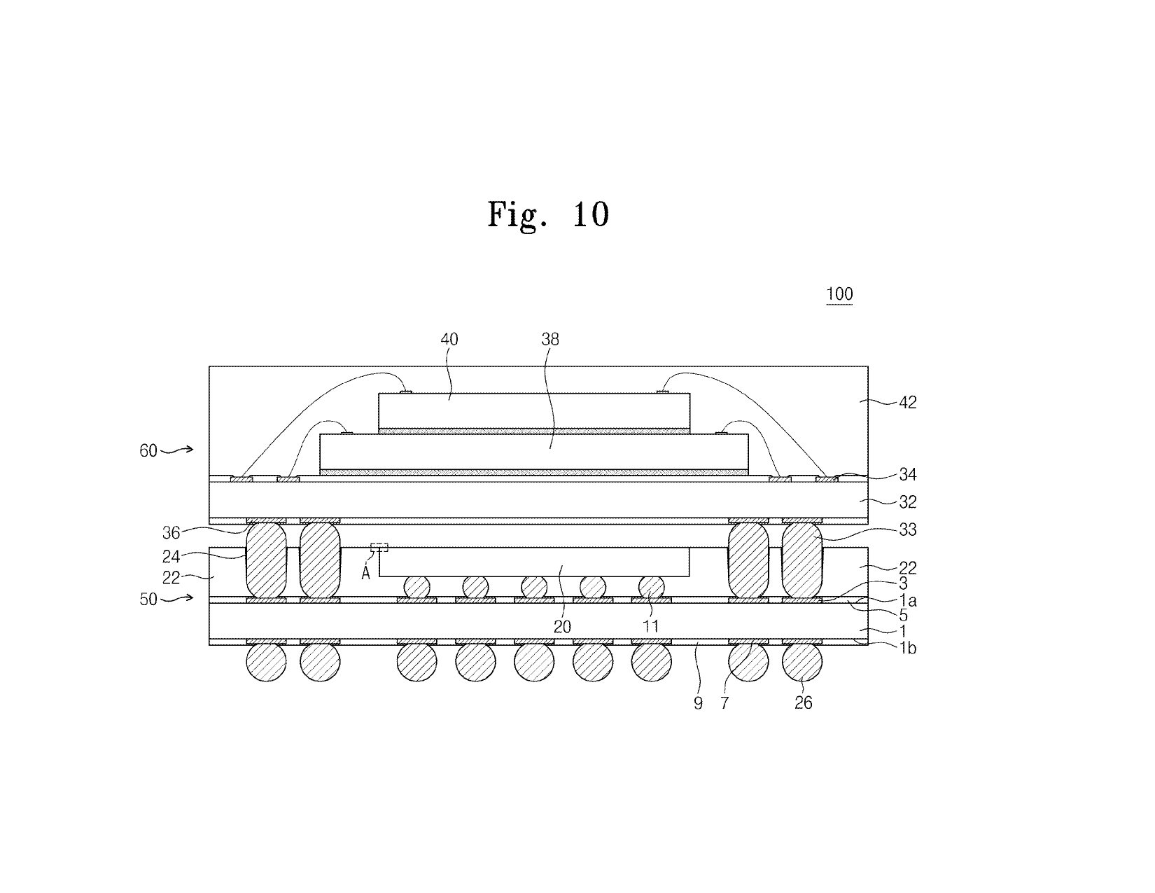

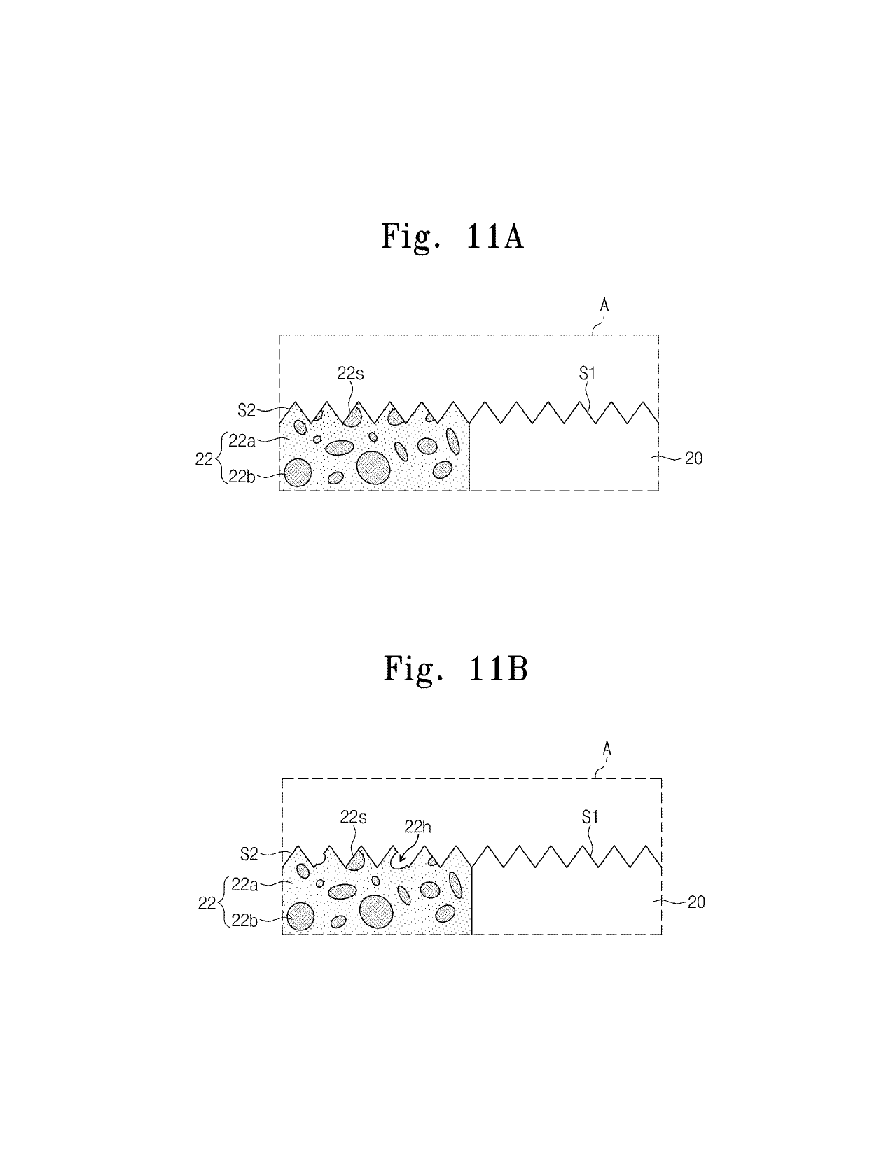

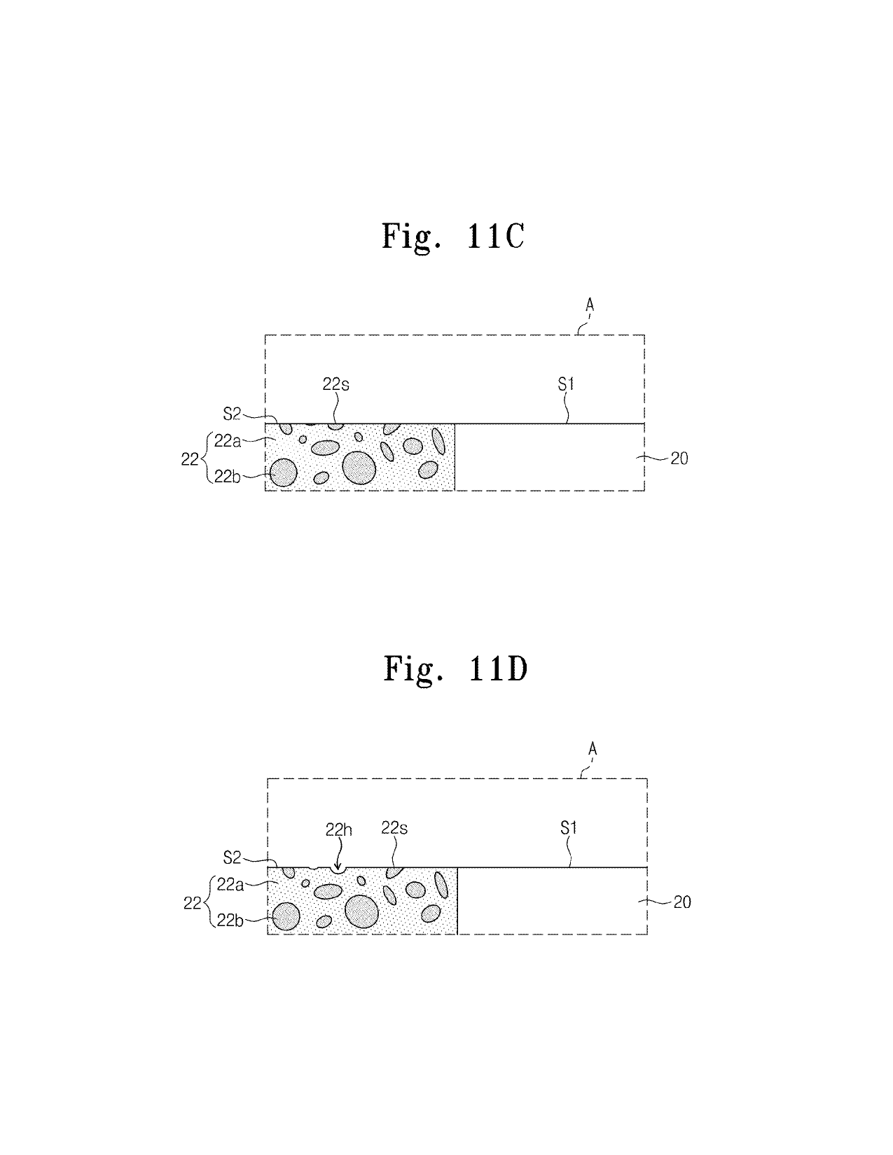

FIG. 1 is a flow chart illustrating a method of fabricating a package-on-package device according to example embodiments of the inventive concept. FIGS. 2, 3A, 4A, 5A, and 6 to 10 are cross-sectional views illustrating a method of fabricating a package-on-package device according to the example embodiments of FIG. 1. FIG. 3B is a cross-sectional view illustrating a modified example of FIG. 3A. FIGS. 4B and 5B are cross-sectional views illustrating a modified example of the example embodiments of FIG. 1. FIGS. 11A to 11D are enlarged views of a portion ‘A’ of FIG. 5A or FIG. 10.

Referring to FIGS. 1 and 2, first, a lower semiconductor package may be fabricated (S 10). A lower package board 1 may be prepared. The lower package board 1 may include a first surface 1a and a second surface 1b opposite to each other. A plurality of first lower ball lands 3 and a first insulating layer 5 partially covering the first lower ball lands 3 may be disposed on the first surface 1a. A plurality of second lower ball lands 7 and a second insulating layer 9 partially covering the second lower ball lands 7 may be disposed on the second surface 1b. Even though not shown in the drawings, vias and/or circuit patterns electrically connecting the lower ball lands 3 and 7 may be formed in the lower package board 1. For example, the lower package board 1 may be a single-layered or multi-layered printed circuit board of a panel/strip size. A lower semiconductor chip 20 may be mounted on the lower package board 1 by using first inner solder balls 11 in a flip chip bonding method (S11). Thus, an electrical path length between the lower semiconductor chip 20 and the lower package board 1 may be reduced, thereby improving a signal transmission speed between the lower semiconductor chip 20 and the lower package board 1. A plurality of lower semiconductor chips 20 may be mounted on one lower package board 1 of the panel/strip size. For example, the one lower package board 1 of the panel/strip size may include a plurality of unit package regions and each of the lower semiconductor chips 20 may be mounted on each of the unit package regions.

Before the lower semiconductor chip 20 is mounted on the lower package board 1, a back-grinding process grinding a portion of the lower semiconductor chip 20 may not performed. Alternatively, even though the back-grinding process may be performed, the lower semiconductor chip 20 may have a thickness thicker than a target-thickness thereof. For example, the lower semiconductor chip 20 may have a first thickness T1 and the first thickness T1 may have, for example, a range of about 300 μm to about 700 μm. Second inner solder balls 13 may be formed on the first lower ball lands 3 adjacent to the lower semiconductor chip 20.

Referring to FIGS. 1, 3A, and 3B, a lower molding layer 22 may be formed to cover the lower package board 1 and at least a sidewall of the lower semiconductor chip 20 (S 12). The lower molding layer 22 may cover a top surface of the lower semiconductor chip 20 as illustrated in FIG. 3A. Alternatively, the lower molding layer 22 may not cover the top surface of the lower semiconductor chip 20 as illustrated in FIG. 3B. The lower molding layer 22 may include a resin layer and a plurality of filler particles dispersed within the resin layer. The resin layer may include at least one polymer material. The filler particle may include a material such as silica or alumina. A process temperature of a process forming the lower molding layer 22 may have a range of about 150 degrees Celsius to 200 degrees Celsius. As described above, the lower molding layer 22 may be formed on the lower semiconductor chip 20 and the lower package board 1. Because the lower semiconductor chip has a thickness T1, which is thicker than the target thickness of the lower semiconductor chip 20, a warpage phenomenon of the lower semiconductor chip 20, which may be caused by the temperature of the lower molding layer 22 forming process, may be relieved or reduced. Additionally, because the lower semiconductor chip 20 is relatively thick before a subsequent grinding to achieve the target thickness, the structure including the relatively thick lower semiconductor chip 20 may be easy to handle. Thus, process convenience may be improved.

Referring to FIGS. 1, 4A, and 5A, a grinding process using a grinding tool 10 such as a diamond wheel or a cutter may be performed to remove an upper portion of the lower molding layer 22 and an upper portion of the lower semiconductor chip 20 (S13). Thus, the lower semiconductor chip 20 may be formed to have a second thickness T2 corresponding to the target-thickness. For example, the second thickness T2 may be equal to or less than about 100 μm. In the present example embodiments, the second inner solder ball 13 may not be exposed by the grinding process.

Top surfaces of the lower molding layer 22 and the lower semiconductor chip 20 after the grinding process may be substantially the same as FIGS. 11A to 11D. The lower semiconductor chip 20 may have a first top surface S1. The lower molding layer 22 may include the resin layer 22a and the filler particles 22b and have a second top surface S2. A center line average roughness Ra or a ten point height of irregularities Rz of each of the first and second top surfaces S1 and S2 may be equal to or less than about 25 μm. The grinding process may be performed to the upper portions of the lower molding layer 22 and the lower semiconductor chip 20 in the same direction. Accordingly, the same pattern may be formed to the first top surface S1 and the second top surface S2 as illustrated in FIG. 11A. Alternatively, as illustrated in FIG. 11C, the first and second top surfaces S1 and S2 may be planarized to have a surface roughness smaller than that of the first and second top surfaces S1 and S2 illustrated in FIG. 11A. The filler particles 22b may be grinded by the grinding process. Thus, each of the filler particles 22b exposed at the second top surface S2 have a planarized top surface 22s. Meanwhile, as illustrated in FIGS. 11B and 11D, if the filler particle 22b having a diameter less than about 50 μm is exposed at the second top surface S2, it may be separated and removed from the lower molding layer 22 during/after the grinding process. Thus, filler holes 22h may be formed at the second top surface S2. The filler holes 22h may be formed at locations where the filler particles 22b having diameters less than about 50 μm were disposed. Thus, diameters of the filler holes 22h may be less than about 50 μm.

Referring to FIG. 6, after the grinding process is finished, a portion of the lower molding layer 22 may be removed using a laser to form a connecting hole 24, through which the second inner solder ball 13 is exposed.

Alternatively, a portion of the lower molding layer 22 may be removed using a laser to form a connecting hole 24 exposing the second inner solder ball 13 before the grinding process is performed as illustrated in FIG. 4B. Referring to FIG. 5B, after forming the connecting hole 24, the grinding process using the grinding tool 10 may be performed to remove upper portions of the lower molding layer 22 and the lower semiconductor chip 20. Thus, the structure of FIG. 6 may be formed.

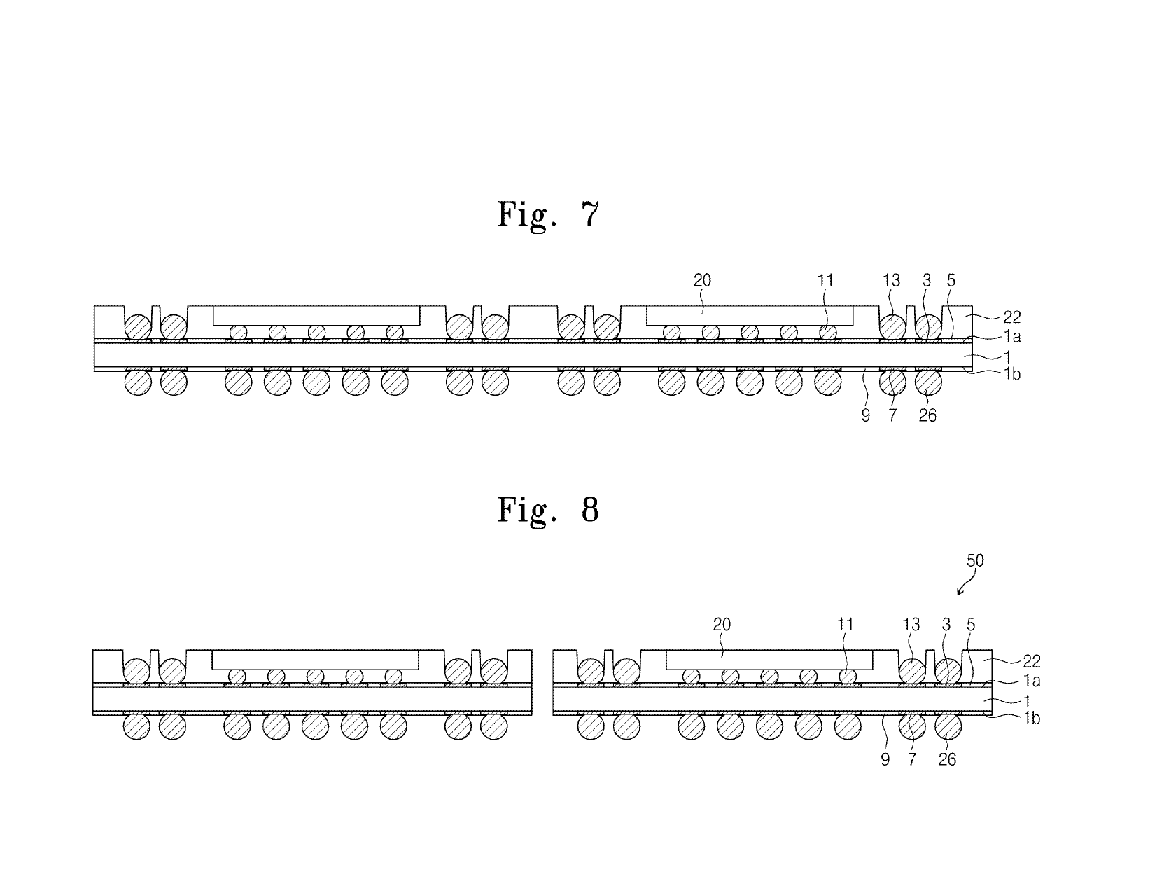

Referring to FIG. 7, each of external solder balls 26 may be formed on the second lower ball lands 7, respectively.

Referring to FIG. 8, a singulation process may be performed to cut the lower molding layer 22 and the lower package board 1 along a boundary between the unit package regions, thereby forming lower semiconductor packages 50.

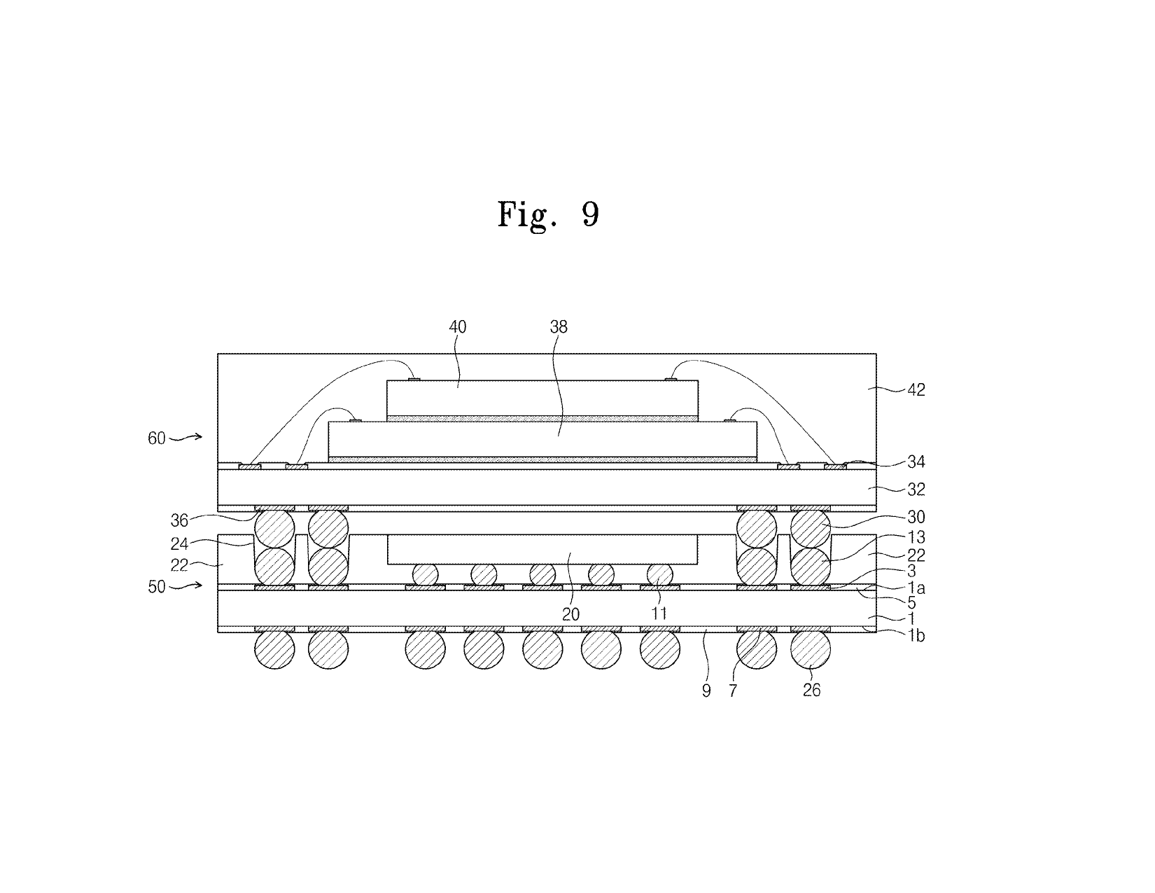

Referring to FIGS. 1 and 9, an upper semiconductor package 60 may be mounted on the lower semiconductor package 50 (S20). First, the upper semiconductor package 60 may be located on the lower semiconductor package 50 with preliminary solder balls 30 therebetween. The upper semiconductor package 60 may include, for example, two upper semiconductor chips 38 and 40 that are mounted on an upper package board 32 in a wire bonding method. First upper pads 34 may be disposed on a top surface of the upper package board 32 and second upper pads 36 may be disposed on a bottom surface of the upper package board 32. The upper semiconductor chips 38 and 40 may be electrically connected to the first upper pads 34 by wires. An upper molding layer 42 may cover the upper semiconductor chips 38 and 40 and the upper package board 32. The preliminary solder ball 30 may be disposed in the connecting hole 24. The preliminary solder ball 30 having a globular or spherical shape may be prevented from being moved to an undesired place by the connecting hole 24. The preliminary solder ball 30 may be in contact with the second upper pad 36.

Referring to FIG. 10, heat of, for example, about 180 degrees Celsius to about 240 degrees Celsius may be applied to the structure of FIG. 9. Thus, the preliminary solder ball 30 and the second inner solder ball 13 may be melted and bonded to each other, thereby forming a connecting solder ball 33. As a result, the upper semiconductor package 60 may be mounted on the lower semiconductor package 50, thereby forming a package-on-package device 100. At this time, the connecting hole 24 may fix the location of the preliminary solder ball 30.

In the present example embodiments, after the lower molding layer 22 is formed, the grinding process may be performed. Thus, the number and/or thermal budget of heating processes for the lower semiconductor package 50 having relatively thin thickness (e.g, the target thickness T2) may be reduced. In more detail, if a lower semiconductor chip having a target-thickness is mounted on a lower package board, the lower semiconductor chip may go through two heating processes, e.g., a process for forming the lower molding layer 22 and a process for forming the external solder balls 26. Thus, the warpage phenomenon may be relatively great due to differences of physical properties (e.g., coefficient of thermal expansion, rigidity, etc.) between the lower semiconductor chip and the lower molding layer.

However, in the present example embodiments, the lower semiconductor chip 20 having the thickness T1, which is thicker than a target thickness T2, may go through the process for forming the lower molding layer 22, and the lower semiconductor chip 20 having the target-thickness T2 after the grinding process may go through the process forming the external solder balls 26. Because the lower semiconductor chip 20 having a relatively thin thickness (e.g., the target thickness T2) is not exposed to, for example, the process for forming the lower molding layer 22, process elements causing the warpage phenomenon may be reduced. Thus, warpage of the package-on-package device 100 may be prevented or reduced.

Referring to FIGS. 10, 11A and 11D, the package-on-package device 100 according to example embodiments may include a lower semiconductor package 50 and an upper semiconductor package 60 mounted on the lower semiconductor package 50. The lower semiconductor package 50 may include a lower package board 1, a lower semiconductor chip 20 mounted on the lower package board 1 in a flip chip bonding method, and a lower molding layer 22. The lower molding layer 22 may cover a sidewall of the lower semiconductor chip 20 and the lower package board 1. The lower molding layer 22 may expose a top surface of the lower semiconductor chip 20. The lower molding layer 22 may include a resin layer 22a and a plurality of filler particles 22b dispersed within the resin layer 22a. At least one filler particle 22b exposed at a second top surface S2 of the lower molding layer 22 of the filler particles 22b may have a planarized top surface 22s. The second top surface S2 of the lower molding layer 22 may have the same pattern as a first top surface S1 of the lower semiconductor chip 20. The second top surface S2 may include at least one filler hole 22h. A diameter of the filler hole 22h may be less than about 50 μm. A center line average roughness Ra or a ten point height of irregularities Rz of a surface roughness of each of the first and second top surfaces S1 and S2 may be equal to or less than about 25 μm.

The lower semiconductor package 50 may further include a connecting hole 24 disposed in the lower molding layer 22, and a second inner solder ball 13 disposed on the lower package board 1 and exposed through the connecting hole 24. The lower semiconductor package 60 may be different from the lower semiconductor package 50. The upper semiconductor package 60 may include an upper package board 32, two upper semiconductor chips 38 and 40 mounted on the upper package board 32 in a wire bonding method, and an upper molding layer 42 covering the upper semiconductor chips 38 and 40 and the upper package board 32.

The package-on-package device 100 of FIG. 10 formed by the method described above may achieve a relatively thin thickness package-on-package device with improved co-planarity, improved resistance to warpage, and/or enhanced process convenience.

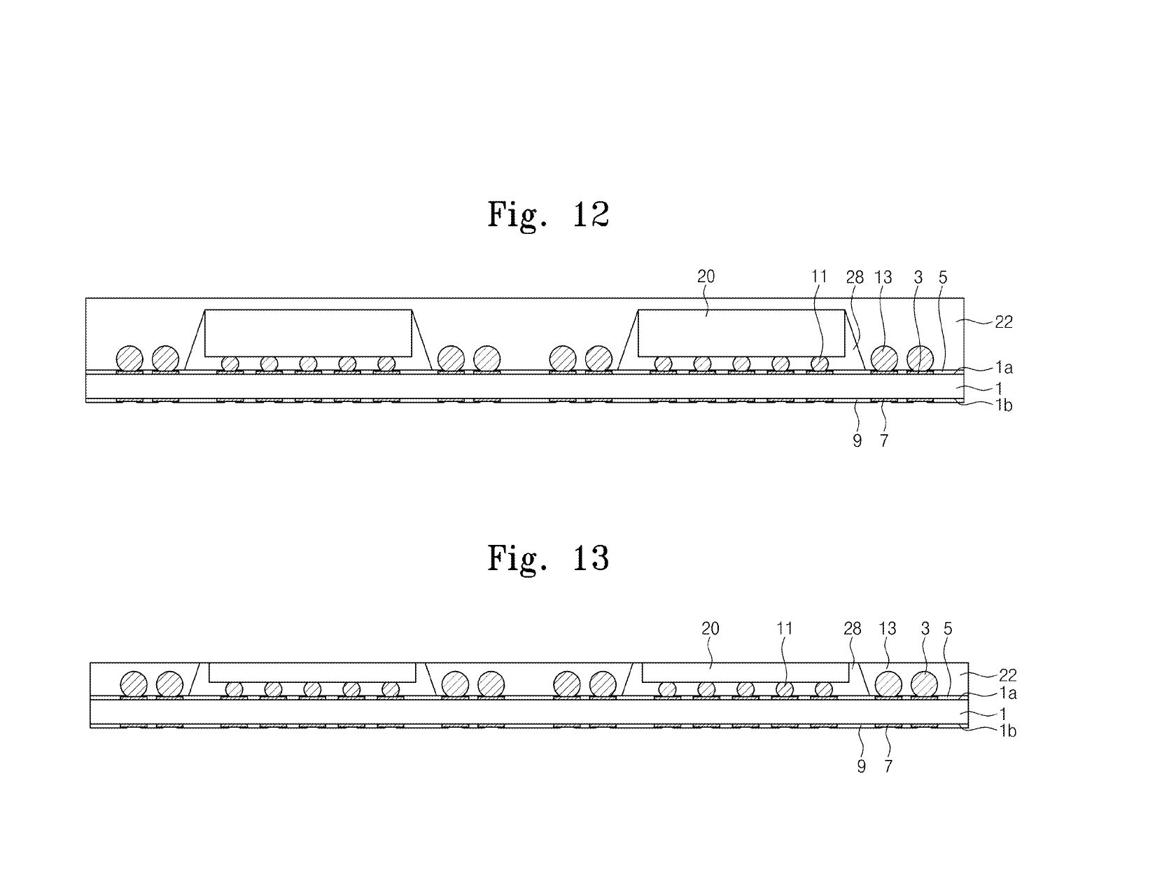

FIGS. 12 to 14 are cross-sectional views illustrating a method of fabricating a package-on-package device according to example embodiment of inventive concepts.

Referring to FIG. 12, an underfill resin layer 28 may be formed to fill a space between the lower semiconductor chip 20 and the lower package board 1 in the structure of FIG. 2. The underfill resin layer 28 may be formed to cover a sidewall of the lower semiconductor chip 20, and the lower molding layer 22 is formed thereon. The underfill resin layer 28 may include a resin layer including polymer material and/or underfill resin fillers dispersed in the resin layer.

Referring to FIG. 13, a grinding process may be performed to remove upper portions of the lower molding layer 22, the underfill resin layer 28, and the lower semiconductor chip 20. Thus, thicknesses of the lower molding layer 22, the underfill resin layer 28, and the lower semiconductor chip 20 may be reduced and top surfaces thereof may be exposed at the same time. The top surfaces of the lower molding layer 22, the underfill resin layer 28, and the lower semiconductor chip 20 may be similar as described above with reference to FIGS. 11A to 11D. For example, the top surface of the underfill resin layer 280 may be similar to the second top surface S2. The top surface of the underfill resin layer 28 may have the same surface roughness and/or the same pattern as the first top surface S1 and the second top surface S2.

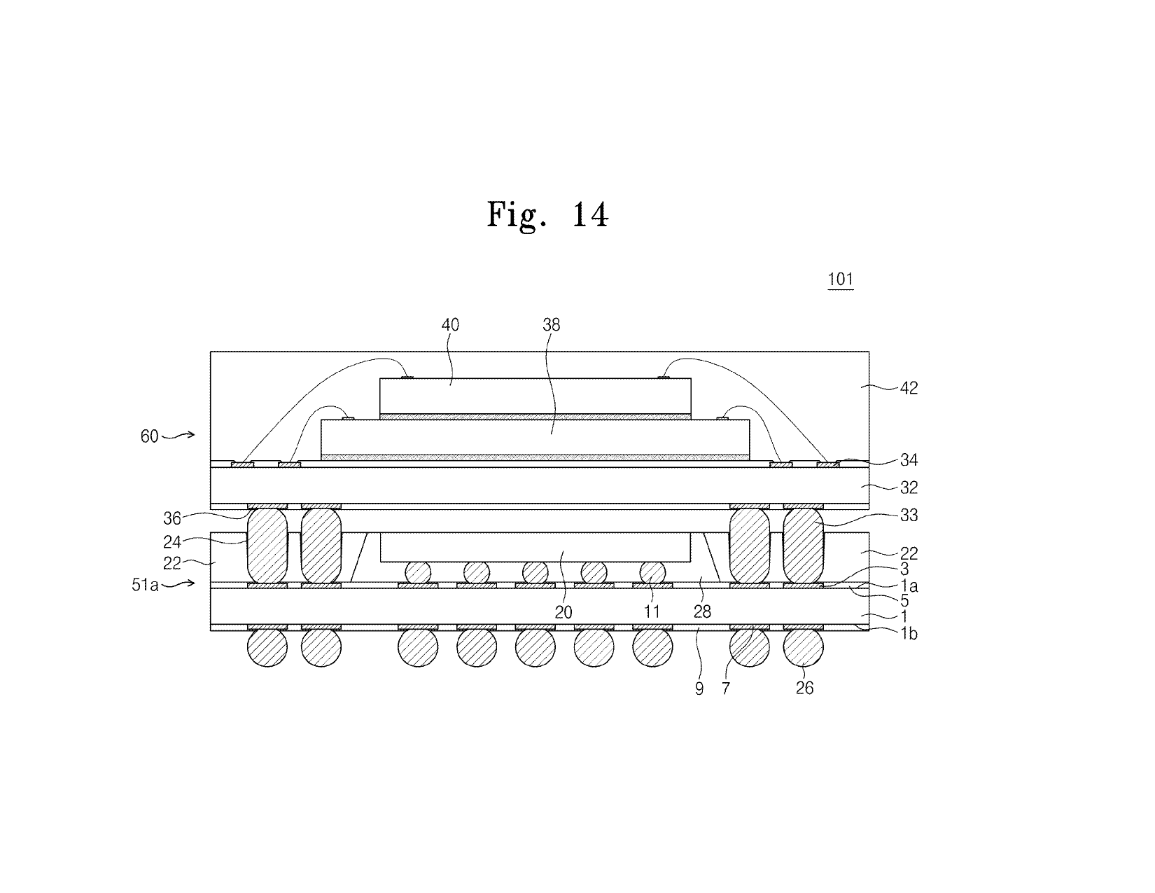

Referring to FIG. 14, subsequent processes as described in the example embodiments of FIG. 1 may be performed to form a lower semiconductor package 51a and then to mount an upper semiconductor package 60 on the lower semiconductor package 51a. Thus, a package-on-package device 101 may be fabricated.

The package-on-package device 101 according to the example embodiments may further include the underfill resin layer 28 disposed between the lower semiconductor chip 20 and the lower package board 1. The underfill resin layer 28 may extend to be disposed between the lower molding layer 22 and the sidewall of the lower semiconductor chip 20. The top surface of the underfill resin layer 22 may have the same pattern as the top surface of the lower molding layer 22.

Other processes/other elements for the package-on-package device 101 may be the same as/similar to corresponding processes/corresponding elements of the example embodiments of FIGS. 1-10.

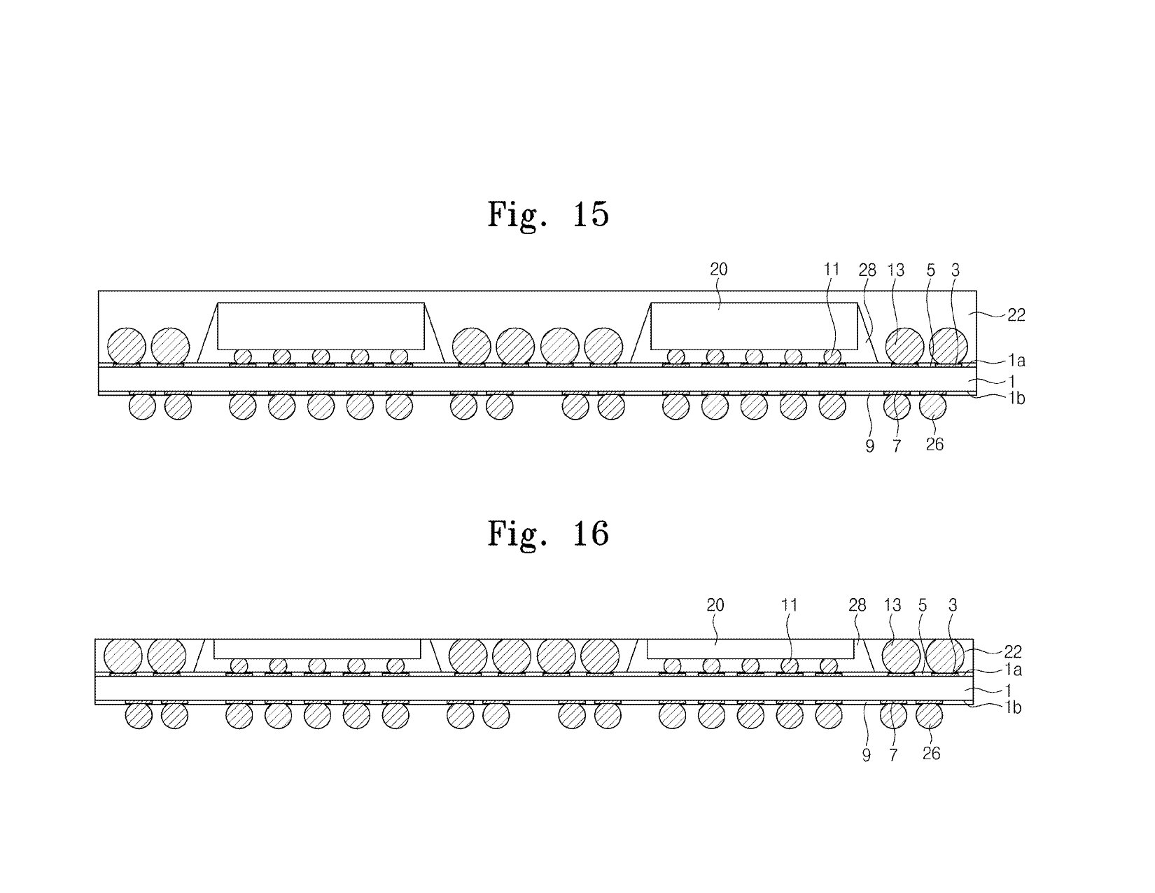

FIGS. 15 to 17 are cross-sectional views illustrating a method of fabricating a package-on-package device according to example embodiments of inventive concepts.

Referring to FIG. 15, as described in the example embodiments of FIGS. 12 to 14, after mounting the lower semiconductor chip 20 in the lower package board 1, the underfill resin layer 28 may be formed. In particular, a second inner solder ball 13 having a diameter greater than that of the second inner solder ball 13 of the example embodiments of FIGS. 12 to 14 may be formed on each of the first lower ball lands 3 beside the lower semiconductor chip 20.

Referring to FIG. 16, a grinding process may be performed to remove upper portions of the lower molding layer 22, the underfill resin layer 28, and the lower semiconductor chip 20. At this time, an upper portion of the second inner solder ball 13 may be partially removed to expose its top surface. The exposed top surface of the second inner solder ball 13 after the grinding process may be similar to one of the first surfaces S1 described with reference to FIGS. 11A to 11D.

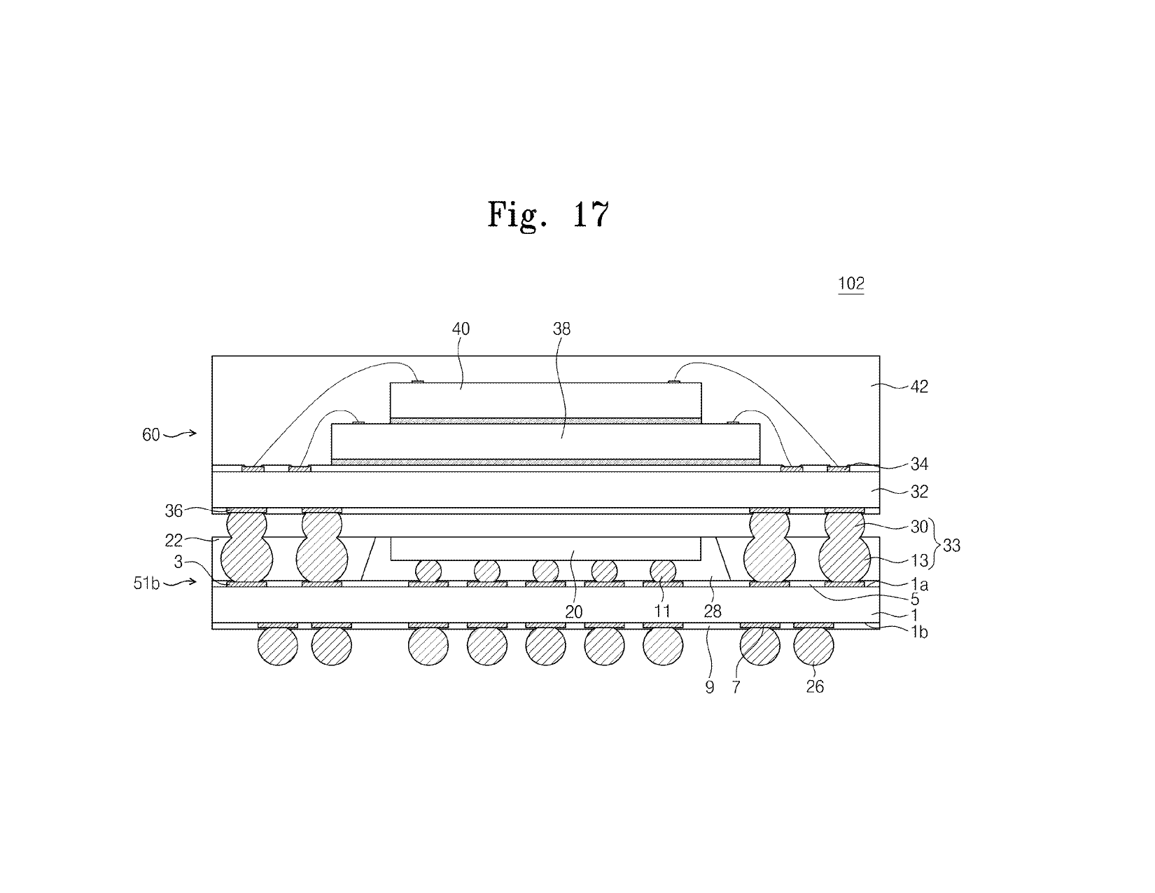

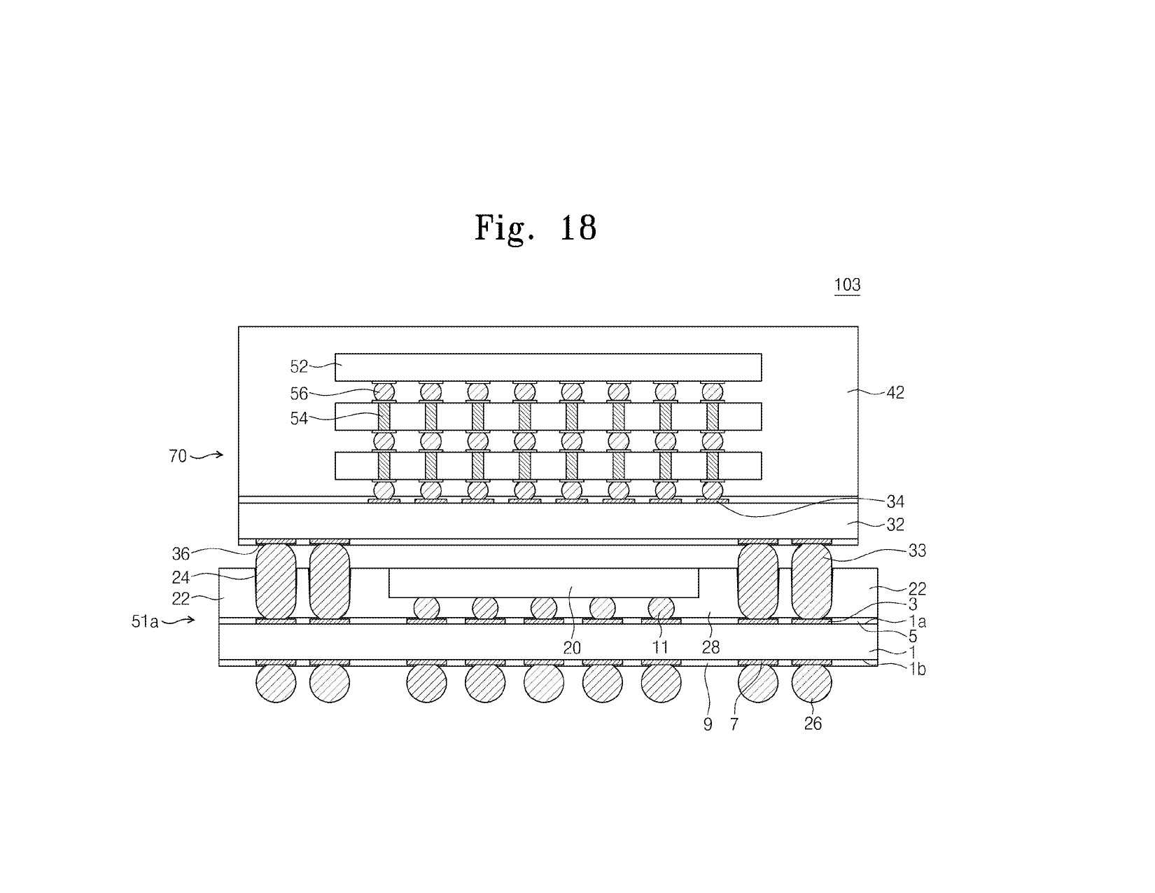

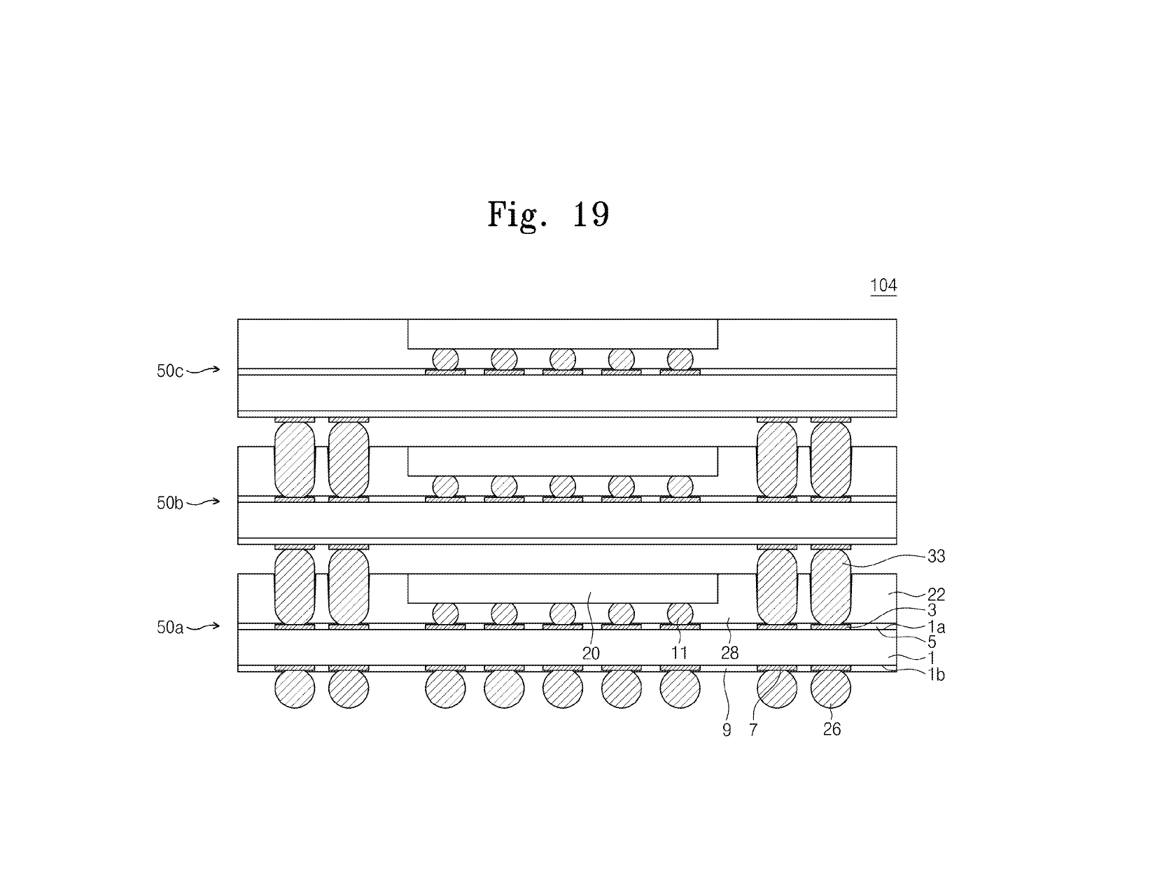

Referring to FIG. 17, because the top surface of the second inner solder ball 13 is exposed after the grinding process, the formation of the connecting hole 24 described in the first embodiment may not be needed. Subsequently, an outer solder ball 26 may be formed and the singulation process may be performed to form a lower semiconductor package 51b. An upper semiconductor package 60 may disposed on the lower semiconductor package 51b with preliminary solder balls 30 therebetween. Then, the heating process may be performed to melt and bond the preliminary solder ball 30 and the second inner solder ball 13. Thus, a connecting solder ball 33 may be formed. As a result, a package-on-package device 102 is fabricated.

In the package-on-package device 102 according to the present example embodiments, the connecting ball 33 may have a snowman-shape. The connecting hole 24 may not be disposed in the lower molding layer 22.

Other processes/other elements for the package-on-package device 102 may be the same as/similar to corresponding processes/corresponding elements of the example embodiments of FIGS. 12 to 14.

FIG. 18 is a cross-sectional view illustrating a package-on-package device according to example embodiments of inventive concepts.

Referring to FIG. 18, an upper semiconductor package 70 may be mounted on the lower semiconductor package 51a of the example embodiments of FIGS. 12 to 14. The upper semiconductor package 70 according to the present example embodiments may include an upper package board 32 and a plurality of upper semiconductor chips 52. The plurality of upper semiconductor chips 52 may be mounted on the upper package board 32 in a flip chip bonding method through upper inner solder balls 56. Each of the upper semiconductor chips 52, if not all, may include through-vias 54 that are respectively overlapped with the upper inner solder balls 56 and are disposed in each of the upper semiconductor chips 52.

Other processes/other elements for the package-on-package device 103 may be the same as/similar to corresponding processes/corresponding elements of the example embodiments of FIGS. 12 to 14.

FIG. 19 is a cross-sectional view illustrating a package-on-package device according to example embodiments of inventive concepts.

Referring to FIG. 19, three semiconductor packages 50a, 50b, and 50c may be stacked together. Each of the semiconductor packages 50a, 50b, and 50c may be the same as the lower semiconductor package 50 of the example embodiments of FIGS. 1-10. Other processes/other elements for the package-on-package device 104 may be the same as/similar to corresponding processes/corresponding elements of the example embodiments of FIGS. 1-10.

The semiconductor package technique described above may be applied to various kinds of semiconductor devices and package modules including the same.

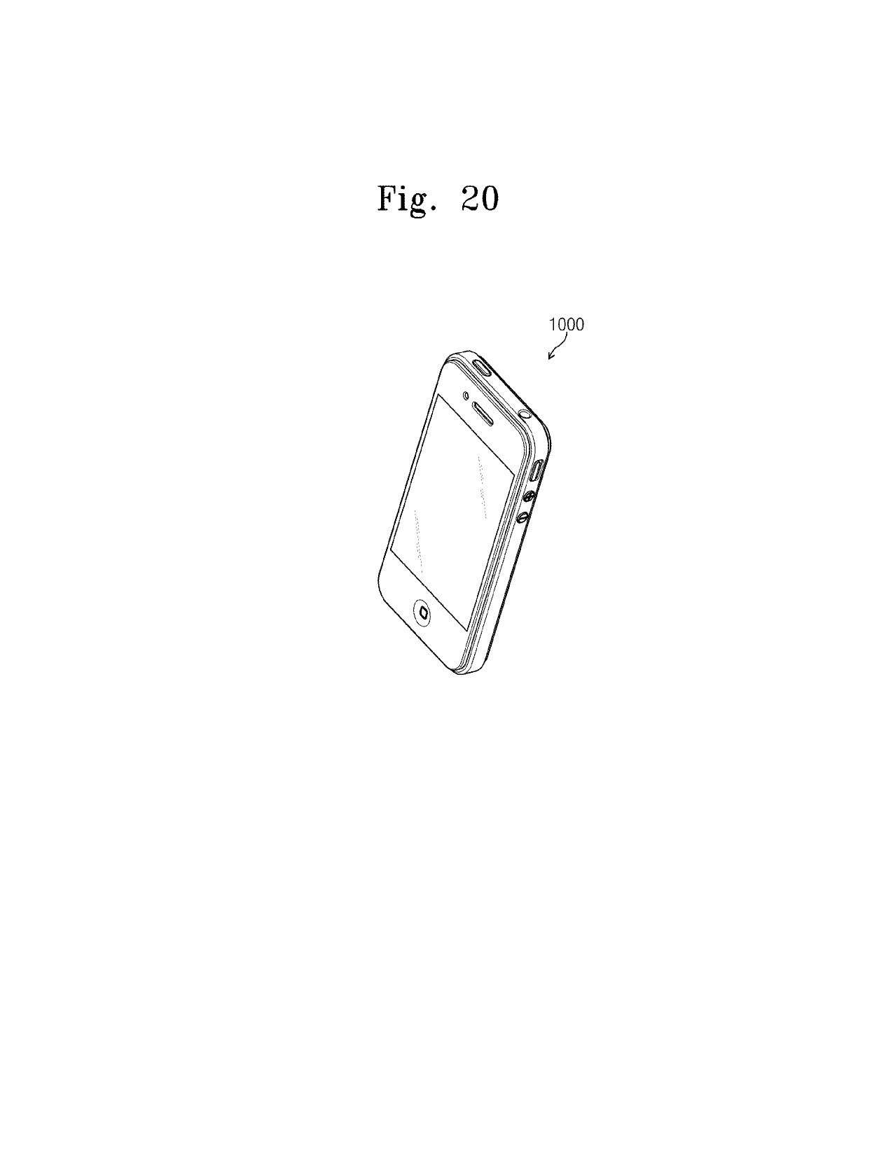

FIG. 20 is a perspective view illustrating an electronic device including at least one of package-on-package devices according to the example embodiments of inventive concepts.

Referring to FIG. 20, the package-on-package devices 100 to 104 according to the example embodiments may be applied to an electronic device 1000, e.g., a smart phone. Because the package-on-package devices according to the example embodiments described above has excellent characteristics in size reduction and performance, the electronic device 1000 with the package-on-package devices, which performs various functions simultaneously, may be advantageous for its lightness, thinness, shortness, and smallness of the electronic device 1000. The electronic device 1000 is not limited to the smart phone illustrated in FIG. 20. In other embodiments, the electronic device 1000 may be realized as various electronic devices such as a mobile electronic device, a laptop computer, a portable computer, a portable multimedia player (PMP), a MP3 player, a camcorder, a web tablet, a wireless phone, a navigation, and/or a personal digital assistant (PDA).

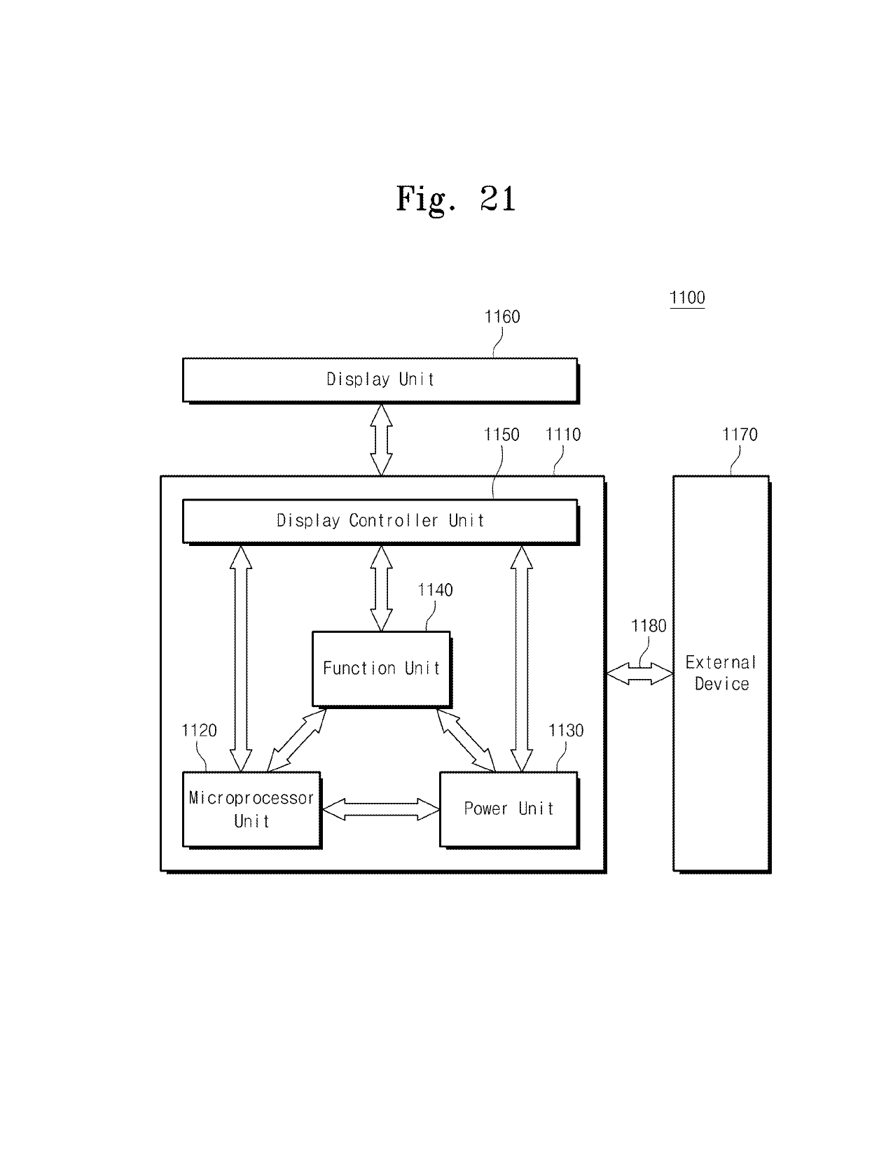

FIG. 21 is a system block diagram illustrating another example of an electronic device applied with at least one of package-on-package devices according to embodiments of inventive concepts.

Referring to FIG. 21, the package-on-package devices 100 to 104 may be applied to an electronic device 1100. The electronic device 1100 may include a body 1110, a microprocessor unit 1120, a power unit 1130, a function unit 1140, and a display controller unit 1150. The body 1110 may be a set board formed of a printed circuit board. The microprocessor unit 1120, the power unit 1130, the function unit 1140, and the display controller unit 1150 may be mounted on the body 1110.

The power unit 1130 may be provided with a predetermined voltage from an external battery (not shown) and then divide the predetermined voltage into desired voltage levels. The power unit 1130 may provide the desired voltage levels to the microprocessor unit 1120, the function unit 1140, and the display controller unit 1150.

The microprocessor unit 1120 may be provided with the voltage from the power unit 1130 and then control the function unit 1140 and a display unit 1160. The function unit 1140 may perform various functions of the electronic device 1100. For example, if the electronic device 1100 is a portable phone, the function unit 1140 may include various elements capable of performing portable phone functions such as dialing, image outputting of the display unit 1160 by communication with an external apparatus 1170, and voice outputting of a speaker. If the electronic device 1100 includes a camera, the function unit 1140 may be a camera image processor. For example, if the electronic device 1100 is connected to a memory card to expand memory capacity, the function unit 1140 may be a memory card controller. The function unit 1140 may communicate with the external device 1170 through a communication unit 1180, which may be, for example, a wireless unit or an electric or optical cable unit. For example, if the electronic device 1100 demands a universal serial bus (USB) for extending functions, the function unit 1140 may be an interface controller. The package-on-package devices 100 to 104 according to the above embodiments may be used as at least one of the microprocessor unit 1120 and the function unit 1140.

The semiconductor package technique described above also may be applied to an electronic system.

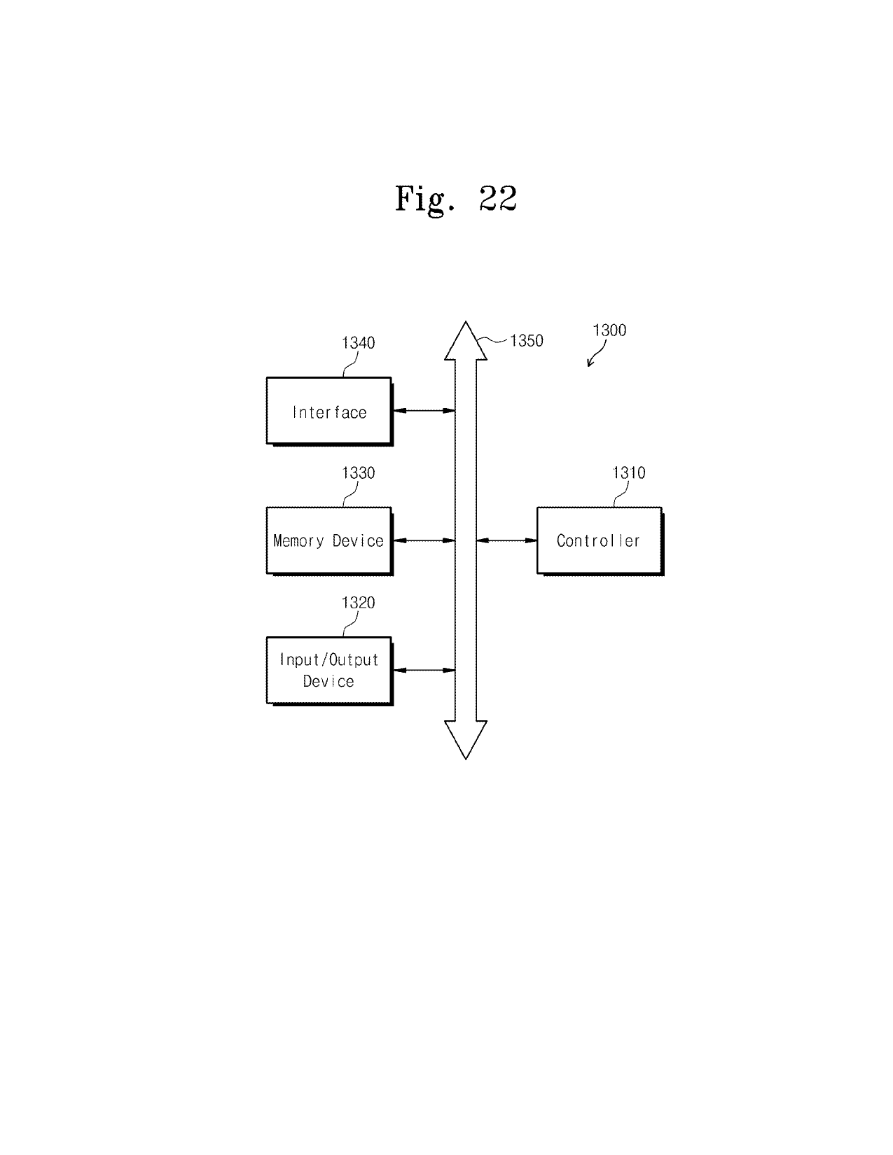

FIG. 22 is a block diagram illustrating an example of electronic systems including at least one of package-on-package devices according to example embodiments of inventive concepts.

Referring to FIG. 22, an electronic system 1300 may include a controller 1310, an input/output device 1320, and a memory device 1330. The controller 1310, the input/output device 1320, and the memory device 1330 may be combined with each other through a bus 1350. The bus 1350 may correspond to a path through which electrical signals are transmitted. For example, the controller 1310 may include at least one of a microprocessor, a digital signal processor, a microcontroller or other logic devices. The other logic devices may have similar functions to any one of the microprocessor, the digital signal processor and the microcontroller. The controller 1310 and the memory device 1330 may include the package-on-package devices according to example embodiments of inventive concepts. The input/output device 1320 may include a keypad, a keyboard and/or a display unit. The memory device 1330 may be a device storing data. The memory device 1330 may store data and/or command executed by the controller 1310. The memory device 1330 may include a volatile memory device and/or a non-volatile memory device. The memory device 1330 may be formed of a flash memory. For example, the flash memory formed by example embodiments above may be installed into the electronic system 1300, e.g., a mobile device or a desk top computer. The flash memory may be realized as a solid state disk (SSD). In this case, the electronic system 1300 may stably store massive data in the memory device 1330. The electronic system 1300 may further include an interface 1340 that may transmit electrical data to a communication network or may receive electrical data from a communication network. The interface 1340 may operate wirelessly or through cable. For example, the interface unit 1340 may include an antenna for wireless communication or a transceiver for cable communication. Although not shown in the drawings, an application chipset and a camera image processor (CIS) may further be provided to the electronic system 1300.

In the methods of fabricating the package-on-package device according to example embodiments of inventive concepts, the lower semiconductor chip may be grinded to have the target-thickness after forming the lower molding layer. Because the lower molding layer is formed when the lower semiconductor chip has a thickness thicker than the target-thickness, the warpage phenomenon caused by, for example, the process temperature of the lower molding layer may be relieved.

Additionally, because the grinding process is performed after forming the lower molding layer, the number and/or thermal budget of heat processes for the lower semiconductor package having relatively thin thickness may be relatively reduced. Thus, the number and/or thermal budget of processes causing the warpage phenomenon may be reduced. Thus, warpage of the package-on-package device may be prevented or reduced. As a result, the package-on-package device fabricated by the methods may have a thin thickness, and may exhibit improved co-planarity, improved resistance to warpage, and/or enhanced process convenience.

Moreover, because the lower semiconductor package is relatively thick before the grinding process is performed, the lower semiconductor package may be easy to handle. Thus, process convenience may be improved.

Furthermore, because the lower semiconductor chip is mounted on the lower package board in the flip chip bonding method, an electrical path length between the lower semiconductor chip and the lower package board may be reduced, thereby improving a signal transmission speed therebetween.

While the inventive concepts has been described with reference to the example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

1. A method of fabricating a package-on-package device, comprising:
fabricating a lower semiconductor package; and
mounting an upper semiconductor package on the lower semiconductor package,
wherein fabricating the lower semiconductor package includes,
mounting a lower semiconductor chip on a lower package board in a flip chip bonding method,
forming a lower molding layer covering at least a sidewall of the lower semiconductor chip and covering the lower package board, and
performing a grinding to remove an upper portion of the lower molding layer and an upper portion of the lower semiconductor chip.

2. The method of claim 1, further comprising:
forming an inner solder ball on the lower package board beside the lower semiconductor chip before forming the lower molding layer.

3. The method of claim 2, further comprising:
partially removing the lower molding layer using a laser to form a connecting hole,
wherein the grinding does not expose the inner solder ball, but the connecting hole formed by the partially removing the lower molding layer exposes the inner solder ball.

4. The method of claim 3, wherein the upper semiconductor package includes a pad opposite to the lower molding layer, and
wherein mounting the upper semiconductor package includes,
locating a preliminary solder ball contacting the pad in the connecting hole, and
melting and bonding the preliminary solder ball and the inner solder ball to each other.

5. The method of claim 2, wherein the grinding exposes the inner solder ball.

6. The method of claim 1, further comprising:
forming an underfill resin layer filling a space between the lower semiconductor chip and the lower package board before forming the lower molding layer,
wherein the grinding exposes the underfill resin layer.

7. The method of claim 1, wherein the lower molding layer includes a resin layer and a plurality of filler particles dispersed in the resin layer; and
wherein the grinding grinds at least one of the filler particles.

8. The method of claim 7, wherein the filler particle exposed at a top surface of the lower molding layer is removed by the grinding such that a filler hole is formed at the top surface of the lower molding layer, the filler particle having a diameter less than about 50 μm.

9. The method of claim 1, wherein the grinding is performed to the upper portions of the lower molding layer and the lower semiconductor chip in the same direction such that the same pattern is formed at top surfaces of the lower molding layer and the lower semiconductor chip.

10.-15. (canceled)

16. A method of fabricating a first semiconductor package comprising:
flip chip bonding a first semiconductor chip onto a first package board;
forming a molding layer to cover the first package board and at least a sidewall of the first semiconductor chip; and
removing an upper portion of the molding layer and an upper portion of the first semiconductor chip to a target thickness.

17. The method of claim 16, further comprising:
forming a first solder ball on the first package board, the first solder ball formed around the first semiconductor chip before the forming a molding layer.

18. The method of claim 17, further comprising:
forming a connecting hole through the molding layer, the connecting hole exposing the first solder ball.

19. The method of claim 18, wherein the forming a connecting hole is carried out at least one of before and after the removing.

20. The method of claim 17, wherein the removing exposes a top surface of the first solder ball.

21. The method of claim 18, further comprising:
mounting a second semiconductor package onto the first semiconductor package, the second semiconductor package including,
a second package board, and
a second semiconductor chip thereon, and
wherein the first and the second semiconductor packages are electrically coupled to each other and constitutes a package-on-package device.

22. The method of claim 21, further comprising:
forming a second solder ball on a surface of the second package board, the surface facing the first semiconductor package.

23. The method of claim 22, wherein the first solder ball formed on the first semiconductor package contacts the second solder ball formed on the second semiconductor package.

24. The method of claim 22, wherein the first solder ball is connected to the second solder ball in the connecting hole, the connecting hole formed in the first semiconductor package.

25. The method of claim 16, further comprising:
thinning the first semiconductor chip to an intermediate thickness before the removing.
